(19) United States
(12) Patent Application Publication
(10) Pub. No.: US 2024/0226955 A9
(43) Pub. Date: Jul. 11, 2024

(54) DEPOSITION APPARATUS

(71) Applicant: Samsung Display Co., LTD., Yongin-si (KR)

(72) Inventors: MINCHUL SONG, Yongin-si (KR); MINGOO KANG, Yongin-si (KR); JUNHYEUK KO, Yongin-si (KR); EUIGYU KIM, Yongin-si (KR); SUKHA RYU, Yongin-si (KR); YOUNGSUN CHO, Yongin-si (KR)

(21) Appl. No.: 18/234,937

(22) Filed: Aug. 17, 2023

(30) Foreign Application Priority Data
Oct. 21, 2022 (KR) 10-2022-0136563

(51) Int. Cl. B05C 13/02; B05C 21/00; H01L 21/683; H10K 71/16

(52) U.S. Cl. CPC B05C 13/02; B05C 21/005; H01L 21/6833; H10K 71/166

(57) ABSTRACT

A deposition apparatus includes: a support module having a plurality of support parts coupled to a target substrate; a base substrate coupled to the support module; a connection member for connecting the plurality of support parts to the base substrate; and a mask assembly configured to mask a deposition material provided to the target substrate. The support module further includes position control parts, which control the plurality of support parts to be movable along a direction axis perpendicular to a major surface of each of the support parts, respectively.

This application claims priority to Korean Patent Application No. 10-2022-0136563, filed on Oct. 21, 2022, and all the benefits accruing therefrom under 35 U.S.C. § 119, the content of which in its entirety is herein incorporated by reference.

### BACKGROUND

The present disclosure herein relates to a deposition apparatus for depositing a deposition material on a substrate.

An electronic apparatus such as a smartphone, a tablet computer, a laptop computer, and a smart television is being developed. Such an electronic apparatus includes a display device in order to provide information. The display device is provided by repeating, multiple times, the following processes including a thin film deposition process for forming a thin film made of a predetermined material onto a substrate surface, a photo-lithography process for exposing a selected portion of the thin film, and a dry or wet etching process for removing the exposed portion of the thin film to form desired patterns. Among these processes, a thin film deposition process, a dry etching process, and the like are generally performed in sealed process chambers, and an electrostatic chuck and the like may be provided in each of the process chambers to fix a substrate.

### SUMMARY

The present disclosure provides a deposition apparatus having improved process reliability.

An embodiment of the invention provides a deposition apparatus including: a support module including a plurality of support parts coupled to a target substrate, a base substrate coupled to the support module, a connection member for connecting the plurality of support parts to the base substrate, and a mask assembly adjacent to the target substrate, and configured to mask a deposition material provided to the target substrate, where the support module further includes position control parts configured to control the plurality of support parts to be movable along a direction axis perpendicular to a major surface of each of the support parts, respectively.

In an embodiment, each of the plurality of support parts may include at least one of the position control parts.

In an embodiment, the mask assembly may include a mask including a plurality of cells, and a frame coupled to the mask.

In an embodiment, the plurality of support parts may include a first support part disposed on a location corresponding to the frame, and a second support part which is movable independently of the first support part.

In an embodiment, at least one of the first support part or the second support part may be provided in plurality.

In an embodiment, the frame may have a step on a surface thereof in contact with the target substrate, and the position control part may include a first position control module provided in the first support part and a second position control module provided in the second support part.

In an embodiment, at least one of the first position control module or the second position control module may be provided in plurality.

In an embodiment, the base substrate may include a separation film for separating the plurality of support parts from each other.

In an embodiment, each of the plurality of support parts may include a body part and a magnetic layer fixed to the body part, and the magnetic layer may include a first insulation layer disposed adjacent to the body part, an electrode disposed under the first insulation layer, and a second insulation layer disposed under the at least one electrode.

In an embodiment, the plurality of support parts may include at least one of the electrodes.

In an embodiment, the plurality of electrodes may be driven for the plurality of support parts, respectively.

In an embodiment, the position control part may be provided in the body part.

In an embodiment of the invention, a deposition apparatus includes: a support module including a plurality of support parts coupled to a target substrate, a movement module coupled to the plurality of support parts such that the plurality of support parts each are movable along a direction axis perpendicular to a major surface each of the support parts, and a mask assembly adjacent to the target substrate, and configured to mask a deposition material provided to the target substrate.

In an embodiment, the movement module may be provided in plurality, and the plurality of movement modules may be coupled to the plurality of support parts, respectively.

In an embodiment, the mask assembly may include a mask including a plurality of cells, and a frame coupled to the mask.

In an embodiment, the plurality of support parts may include a first support part disposed on a location corresponding to the frame, and a second support part which is movable independently of the first support part, and at least one of the first support part or the second support part may be provided in plurality.

In an embodiment, the frame may have a step on a surface thereof in contact with the target substrate, the movement module may include a first movement member coupled to the first support part, and a second movement member coupled to the second support part, and at least one of the first movement member or the second movement member may be provided in plurality.

In an embodiment, the deposition apparatus may further include a base substrate coupled to the support module.

In an embodiment, the base substrate may include position control parts configured to control the plurality of support parts to be movable along a direction axis perpendicular to a major surface of each of the support parts, respectively.

In an embodiment, the plurality of support parts may include a first insulation layer, a plurality of electrodes disposed on the first insulation layer, and a second insulation layer disposed on the plurality of electrodes.

### BRIEF DESCRIPTION OF THE FIGURES

The accompanying drawings are included to provide a further understanding of the invention, and are incorporated in and constitute a part of this specification. The drawings illustrate embodiments of the invention and, together with the description, serve to explain principles of the invention. In the drawings:

FIG. 1 is a side view of a deposition apparatus according to an embodiment of the invention;

FIG. 2 is an exploded perspective view of a mask assembly according to an embodiment of the invention;

FIG. 3 is a perspective view illustrating a portion of a deposition apparatus according to an embodiment of the invention;

FIG. 4A is a cross-sectional view of a deposition apparatus taken along line I-I′ of FIG. 3.

FIG. 4B is a cross-sectional view of a deposition apparatus according to an embodiment of the invention;

FIG. 5A is a plan view of support parts according to an embodiment of the invention;

FIG. 5B is a plan view of support parts according to an embodiment of the invention;

FIG. 6A is a cross-sectional view illustrating a partial configuration of a deposition apparatus according to an embodiment of the invention;

FIG. 6B is cross-sectional view illustrating a partial configuration of a deposition apparatus according to an embodiment of the invention;

FIG. 7 is a cross-sectional view illustrating a partial configuration of a deposition apparatus according to an embodiment of the invention;

FIG. 8 is a cross-sectional view illustrating a partial configuration of a deposition apparatus according to an embodiment of the invention;

FIG. 9A a cross-sectional view illustrating a partial configuration of a deposition apparatus according to an embodiment of the invention; and

FIG. 9B a cross-sectional view illustrating a partial configuration of a deposition apparatus according to an embodiment of the invention.

### DETAILED DESCRIPTION

The invention may be implemented in various modifications and have various forms and specific embodiments are illustrated in the drawings and described in detail in the text. It is to be understood, however, that the invention is not intended to be limited to the particular forms disclosed, but on the contrary, is intended to cover all modifications, equivalents, and alternatives falling within the spirit and scope of the invention.

In this specification, it will be understood that when an element (or a region, a layer, a portion, or the like) is referred to as being “on”, “connected to” or “coupled to” another element, it may be directly disposed on, connected or coupled to the other element, or intervening elements may be disposed therebetween.

Like reference numerals or symbols refer to like elements throughout. In the drawings, the thickness, the ratio, and the size of the element are exaggerated for effective description of the technical contents.

As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the scope of the invention. Similarly, a second element, component, region, layer or section may be termed a first element, component, region, layer or section. As used herein, the singular forms, “a”, “an” and “the” are intended to include the plural forms as well, unless the context clearly indicates otherwise.

Also, terms of “below”, “on lower side”, “above”, “on upper side”, or the like may be used to describe the relationships of the elements illustrated in the drawings. These terms have relative concepts and are described on the basis of the directions indicated in the drawings.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be further understood that the terms “includes” and/or “have”, when used in this specification, specify the presence of stated features, integers, steps, operations, elements, components, and/or groups thereof, but do not preclude the presence or addition of one or more other features, integers, steps, operations, elements, components, and/or groups thereof.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein. Hereinafter, embodiments of the invention will be described with reference to the accompanying drawings.

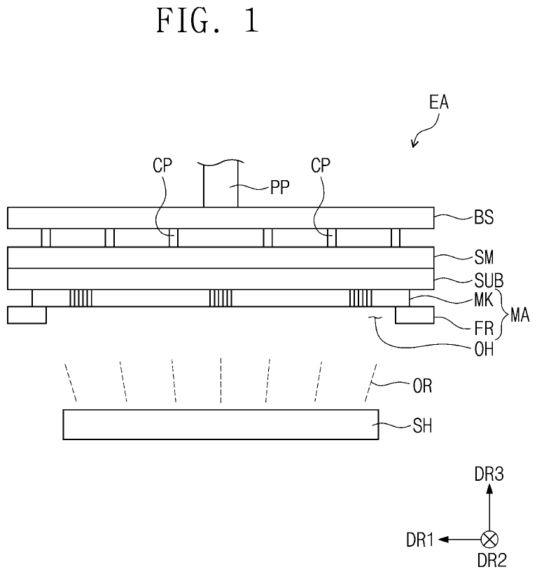

FIG. 1 is a side view of a deposition apparatus according to an embodiment of the invention.

Referring to FIG. 1, a deposition apparatus EA may include a deposition head SH, a target substrate SUB, a mask assembly MA, a support module SM, a base substrate BS, and a driving part PP.

The deposition head SH may spray a deposition material OR to the outside. According to an embodiment of the invention, the deposition head SH may be a shower head. The deposition material OR may be a sublimable or a vaporizable material including one or more of an inorganic material, a metal material, or an organic material. The deposition material OR according to an embodiment may include an organic material which is for producing an organic light-emitting layer.

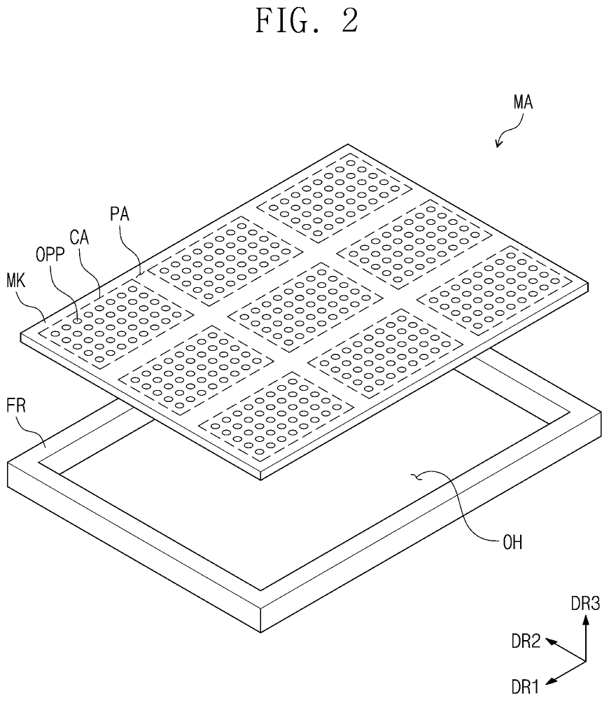

The mask assembly MA may be disposed on a target substrate SUB adjacent to the target substrate SUB, and mask the deposition material OR provided to the target substrate SUB. The mask assembly MA may be opposed to the deposition head SH. The mask assembly MA may include a frame FR and a mask MK. The deposition material OR may pass through a plurality of through-holes OPP (see FIG. 2) included in the mask MK to be deposited onto the target substrate SUB.

The target substrate SUB may have a surface parallel to a plane defined by a first direction DR1 and a second direction DR2. A third direction DR3 may indicate a thickness direction of the target substrate SUB. A front surface (or upper surface) and a rear surface (or lower surface) of the target substrate SUB may be distinguished with respect to the third direction DR3. The third direction DR3 may be a direction crossing the first direction DR1 and the second direction DR2. For example, the first direction DR1, the second direction DR2, and the third direction DR3 may be orthogonal to each other. The target substrate SUB may include a conductive material. For example, the target substrate SUB may include a circuit element layer connected to an organic light-emitting layer. The circuit element layer may include a circuit element (e.g., a transistor and/or a capacitor) for driving a light-emitting element included in the organic light-emitting layer.

The support module SM may be disposed on the target substrate SUB. The support module SM may fix the target substrate SUB on a mask MK and a frame FR. According to an embodiment of the invention, the support module SM may include magnetic substances to bring the target substrate SUB and the mask MK into close contact with each other. In particular, the magnetic substances may generate magnetic forces to fix the mask MK to the target substrate SUB, and to bring the target substrate SUB which is disposed between the mask MK and the support module SM into close contact with the mask MK. Alternatively, the support module SM may include a jig or a robot arm for holding the mask MK.

Although not illustrated in the drawing, the deposition apparatus EA may further include a temperature control module for controlling a temperature of the target substrate SUB. In particular, the temperature control module may cool the target substrate SUB. As the temperature of the target substrate SUB is maintained low by the temperature control module, the deposition material OR may be deposited onto the target substrate SUB.

The base substrate BS may be disposed on the support module SM. According to what is illustrated in the drawing, the base substrate BS is spaced apart from the support module SM. However, an embodiment of the invention is not limited thereto, and the base substrate BS may be disposed in contact with the support module SM. The base substrate BS may serve to protect the support module SM. Therefore, the base substrate BS may be made of a rigid metal. However, an embodiment of the invention is not limited thereto, and the base substrate BS may include an elastic material such as rubber.

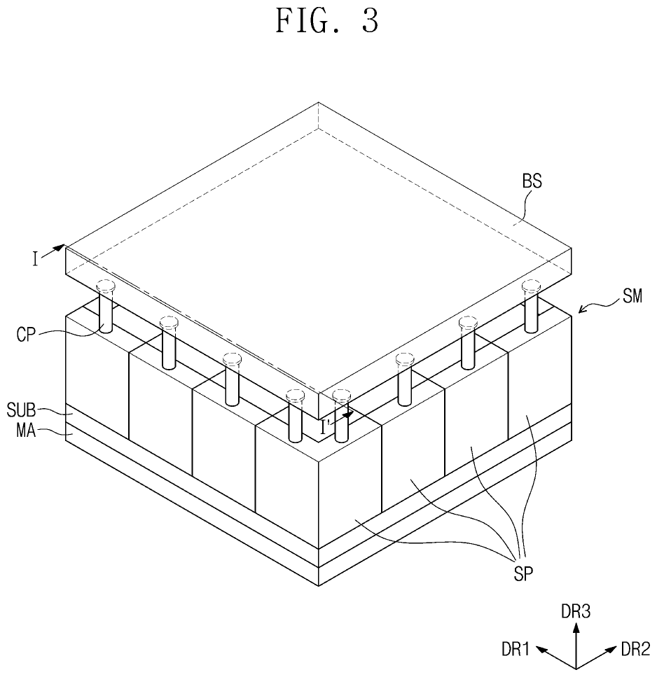

Connection members CP may be disposed between the support module SM and the base substrate BS. The connection members CP may be members connecting the support module SM to the base substrate BS. The connection members CP will be described in detail later with reference to FIG. 3.

The driving part PP may be disposed on the base substrate BS. The support module SM may be disposed on the target substrate SUB, and the support module SM may chuck the target substrate SUB in various directions by operations of the driving part PP. According to an embodiment of the invention, the direction perpendicular to the upper surface of the support module SM and the direction perpendicular to the upper surface of the target substrate SUB chucked by the support module SM may change according to the operation of the driving part PP.

Although not illustrated in the drawing, a chamber provides a sealed space. The deposition apparatus EA may be disposed in the chamber. The chamber may include at least one gate. The chamber may be opened and closed by the gate. The target substrate SUB may enter and exit the chamber through the gate provided in the chamber. That is, when a deposition process starts or ends, the target substrate SUB may be detached from the support module SM and transferred to the outside of the chamber.

Although not illustrated in the drawing, the deposition apparatus EA may further include a stage. The stage may move the mask assembly MA up and down. The stage may extend toward the deposition head SH to be connected to a lifting/lowering device which is disposed on an inner surface of the chamber and moves the target substrate SUB. A space in which a device and the like is disposed may be formed under the target substrate SUB since the stage extends toward the deposition head SH at a location in which the stage does not overlap the target substrate SUB. The stage may not overlap a hole OH of the frame FR. That is, the stage may be disposed out of the movement path of the deposition material OR provided from the deposition head SH to the target substrate SUB.

FIG. 2 is an exploded perspective view of a mask assembly according to an embodiment of the invention.

Referring to FIG. 2, a mask assembly MK may include a frame FR and a mask MK. The frame FR may have a shape of a quadrilateral loop on a plane. In this specification, the surface defined by a first direction DR1 and a second direction DR2 is defined as a plane. As used herein, the term “on a plane” may be defined as being seen from a third direction DR3. That is, a hole OH may be defined in the center of the frame FR. The hole OH may be a hole passing through from the upper surface of the frame FR to the lower surface of the frame FR.

FIG. 2 illustrates that the frame FR has a shape of the quadrilateral loop as an embodiment of the invention, but the shape of the frame FR is not limited thereto. For example, the frame FR may have various shapes such as a circular loop and a polygonal loop. FIG. 2 exemplarily and briefly illustrates that the frame FR is disposed under the mask MK and supports the mask MK, but an embodiment of the invention is not limited thereto. Thus, the frame FR may be disposed above and under the rim of the mask MK to support the mask MK, and may pull and fix the mask MK in the first direction DR1 and the second direction DR2 so as to prevent the mask MK from sagging.

The mask MK according to an embodiment of the invention may include a plurality of cells CA arranged along the first direction DR1 and the second direction DR2. In this embodiment, it is illustrated that the plurality of cells CA are spaced apart from each other along the first direction DR1 and the second direction DR2. However, this is merely an example, the cells CA may be arranged along either of the first direction DR1 or the second direction DR2, and the arrangement is not limited to any one embodiment of the invention.

A plurality of through-holes OPP may be defined in each of the plurality of cells CA. The through-holes OPP may be arranged apart from each other along the first direction DR1 and the second direction DR2. The through-holes OPP may each be defined through the mask MK along the thickness direction DR3 (hereinafter, referred to as the third direction) of the mask MK.

The mask MK according to an embodiment may include a plurality of cells CA and an extension region PA surrounding each of the plurality of cells CA. By the extension region PA, each of the plurality of cells CA may be connected so that the mask MK may have an integrated plate shape. However, an embodiment of the invention is not limited thereto, and the mask MK according to another embodiment of the invention may include a plurality of mask sticks extending along any one of the first direction DR1 or the second direction DR2, and spaced apart from each other.

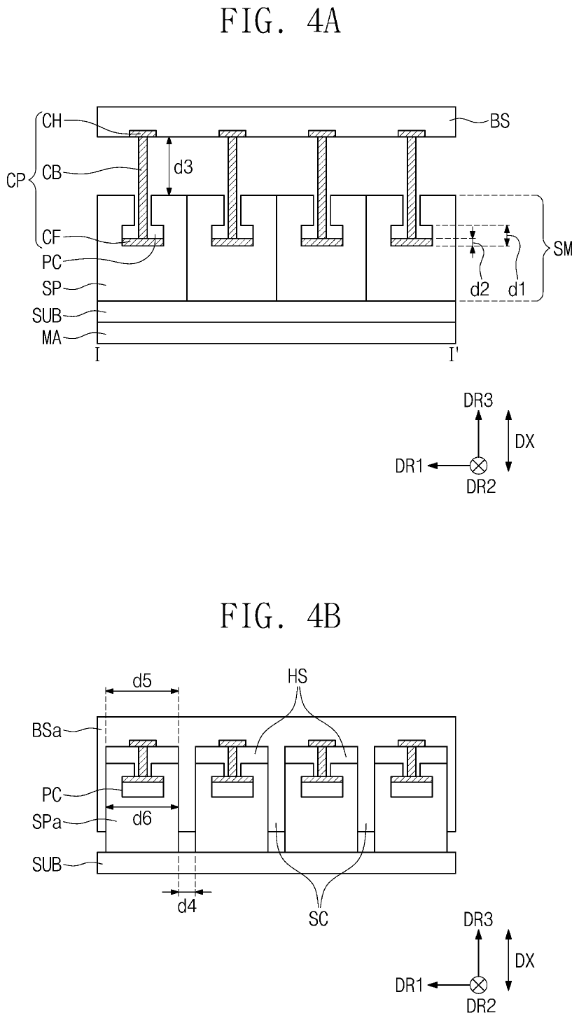

FIG. 3 is a perspective view illustrating a portion of a deposition apparatus according to an embodiment of the invention. FIG. 4A is a cross-sectional view of the deposition apparatus taken along line I-I′ of FIG. 3. FIG. 4B is a cross-sectional view of a deposition apparatus according to an embodiment of the invention.

Referring to FIG. 3, a support module SM may include a plurality of support parts SP coupled to a target substrate SUB. The plurality of support parts SP may be arranged in a first direction DR1 and a second direction DR2, but the number of the arranged support parts is not limited. According to an embodiment of the invention, each of the plurality of support parts SP may have a quadrilateral shape on a plane. However, an embodiment of the invention is not limited thereto, and the support parts SP may have various shapes including polygons such as triangles and pentagons, circles, ovals, and the like. Each of the plurality of support parts SP may have a different area size and shape on a plane. It is illustrated that the plurality of support parts SP are disposed with the side surfaces thereof in contact with each other. However, an embodiment of the invention is not limited thereto, and the plurality of support parts SP may be spaced apart from each other by a predetermined distance in the first direction DR1 or the second direction DR2.

A support module SM may chuck or de-chuck the target substrate SUB by using electrostatic force. In particular, in order to proceed with a process of treating the target substrate SUB, the support module SM may repeat the processes including chucking the target substrate SUB, and de-chucking the target substrate SUB for the next process after the target substrate SUB is processed.

According to an embodiment of the invention, the support module SM may be an electrostatic chuck. The support module SM may include a main body that is formed of a ceramic material or the like, and an electrode which is embedded in the main body and to which power is applied. When voltage is applied to the electrode of the support module SM, the support module SM may have electrostatic force generated by electrostatic induction.

Connection members CP may be disposed to correspond to the plurality of support parts SP, respectively. However, an embodiment of the invention is not limited thereto, and a plurality of connection members CP may be disposed in each of the plurality of support parts SP. The plurality of connection members CP may each have a circular shape on a plane as illustrated in FIG. 3, but the shape is not limited thereto, and the plurality of connection members CP may have various shapes including polygons such triangles and quadrangles, ovals, and the like. The material of the plurality of connection members CP is not limited, and may include, for example, a metal material, an elastic material, or the like.

Referring to FIG. 4A, the support module SM may include position control parts PC for controlling the plurality of support parts SP to be movable along a direction axis perpendicular to a major surface of each of the support parts Sp, respectively. Here, the major surface of each of the support parts Sp is defined as a bottom surface of each of the support parts Sp parallel to a plane defined by the first direction DR1 and the second direction DR2.

According to an embodiment of the invention, a direction axis DX perpendicular to a major surface of each of the support parts SP may be parallel to the third direction DR3. Accordingly, each of the plurality of support parts SP may move in the third direction DR3 or in the opposite direction of the third direction DR3 along the direction axis DX. However, an embodiment of the invention is not limited thereto, and depending on the direction in which the plurality of support parts SP are disposed, the direction axis DX perpendicular to a major surface of each of the support parts SP may be parallel to the first direction DR1 or to the second direction DR2 in another embodiment.

The connection members CP may be fixed to the base substrate BS and to the plurality of support parts SP, respectively, and may connect the base substrate BS to the plurality of support parts SP. The connection members CP may each include a connection head part CH connected to the base substrate BS, a connection bottom part CF connected to the support module SM, and a connection body part CB for connecting the connection head part CH to the connection bottom part CF.

The connection head part CH may be fixed to the lower surface of the base substrate BS. According to what is illustrated in the drawing, the connection head part CH has a rectangular shape in cross section, but the shape is not limited thereto, and the connection head part CH may have various shapes such as trapezoid or semi-sphere.

The connection body part CB may connect the connection head part CH and the connection bottom part CF, and may have a stick shape in cross section. The connection body part CB may have a material same as the materials of the connection head part CH and the connection bottom part CF. According to an embodiment of the invention, the connection body part CB may be an elastic member. When the connection body part CB is an elastic member, due to the gravitational force on the plurality of support parts SP, the connection body part CB may extend from the lower surface of the base substrate BS toward the opposite direction of the third direction DR3. In addition, even without the position control part PC, each of the plurality of support parts SP may move freely up and down along the direction axis DX due to the elastic member.

The connection bottom parts CF may be fixed and connected to the support module SM. In particular, the connection bottom parts CF may be disposed in the position control parts PC included in the plurality of support parts SP, respectively. According to what is illustrated in the drawing, the shape of the connection bottom parts CF in cross section is fixed as a rectangle, but the shape is not limited thereto. The connection bottom parts CF may serve to limit the respective ranges in which the plurality of support parts SP may move in the position control parts PC.

The plurality of support parts SP may each include at least one position control part PC. However, an embodiment of the invention is not limited thereto, and each of the plurality of support parts SP may include a plurality of position control parts PC the number of which corresponds to the number of the connection members CP provided in plurality. The position control parts PC may be spaces in which the connection bottom parts CF connected to the plurality of support parts SP, respectively, are provided. That is, the position control parts PC may be defined as the spaces in which the connection bottom parts CF are disposed. The position control parts PC may control the plurality of support parts SP respectively to be movable along the direction axis DX. In particular, when the position control part PC has a height d1 defined along the third direction DR3, and the connection bottom part CF has a thickness d2 defined along the third direction DR3, a movable range of each of the plurality of support parts SP may be set by the difference between the height d1 of the position control part PC and the thickness d2 of the connection bottom part CF. The difference between the maximum and the minimum values of a distance d3 between the base substrate BS and the plurality of support parts SP may be equal to the difference between the height d1 of the position control part PC and the thickness d2 of the connection bottom part CF. The minimum value of the distance d3 between the base substrate BS and the plurality of support parts SP may be about 0. That is, when the plurality of support parts SP move maximally in the opposite direction of the third direction DR3, the base substrate BS and the plurality of support parts SP may come into contact with each other.

FIG. 4A illustrates that the target substrate SUB is attached under the plurality of support parts SP, the target substrate SUB is in contact with the mask assembly MA, and thus each of the plurality of support parts SP receives force in the third direction DR3 to move maximally in the third direction DR3. Although not illustrated in the drawing, according to a comparative example in which the mask assembly MA is omitted, each of the plurality of support parts SP receives gravity in the opposite direction of the third direction DR3, and moves maximally in the opposite direction of the third direction DR3 due to the gravity. Accordingly, in the position control part PC, the connection bottom part CF reflectively moves in the opposite direction of the third direction DR3 until the connection bottom part CF reaches the upper surface of the position control part PC. That is, each of the plurality of support parts SP according to an embodiment of the invention may move freely up and down along the direction axis DX by the difference between the height d1 of the position control part PC and the thickness d2 of the connection bottom part CF in the process of the target substrate SUB coming into contact with the mask assembly MA.

Although not illustrated in the drawing, a magnet unit including a magnet may be disposed on the base substrate BS. A mask made of metal may be pulled by magnetic forces of the magnet included in the magnet unit, thereby preventing the mask from sagging. In particular, the magnet included in the magnet unit may provide magnetic forces onto the target substrate SUB, and may thus prevent the center of the mask MK from sagging due to lowering of the target substrate SUB.

Referring to FIG. 4B, a base substrate BSa may include separation films SC for separating a plurality of support parts SPa. According to an embodiment of the invention, the separation film SC may be defined as a portion protruding from the base substrate BS illustrated in FIG. 4A. However, an embodiment of the invention is not limited thereto, and the separation film SC may be a separate member attached to the base substrate BS illustrated in FIG. 4A in another embodiment. A thickness d4 of the separation film SC along a first direction DR1 may be equal to the distance by which the plurality of support parts SPa are spaced apart from each other. The thicknesses d4 of the separation films SC may be equal to each other, but an embodiment of the invention is not limited thereto, and the thicknesses d4 may be different from each other in another embodiment.

A plurality of accommodation grooves HS may be defined in the base substrate BSa by the separation films SC. That is, the separation films SC serve to separate the plurality of support parts Spa, respectively, by providing the plurality of accommodation grooves HS. The plurality of support parts SPa may be inserted in the plurality of accommodation grooves HS, respectively. The plurality of accommodation grooves HS may be defined corresponding to the plurality of support parts Spa, respectively. That is, one support part SPa among the plurality of support parts SPa may be disposed in one accommodation groove HS among the plurality of accommodation grooves HS. However, an embodiment of the invention is not limited thereto, and a plurality of support parts SPa may be disposed in one accommodation groove HS. According to an embodiment of the invention, a width d5 of the accommodation groove HS along the first direction DR1 may be equal to a width d6 of the support part SPa along the first direction DR1. However, an embodiment of the invention is not limited thereto, and the width d5 of the accommodation groove HS may be greater than the width d6 of the support part SPa, and thus the support part SPa may move freely when moving along the direction axis DX.

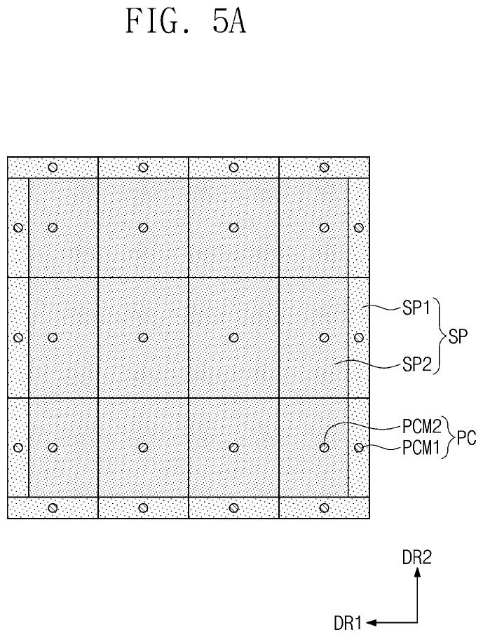

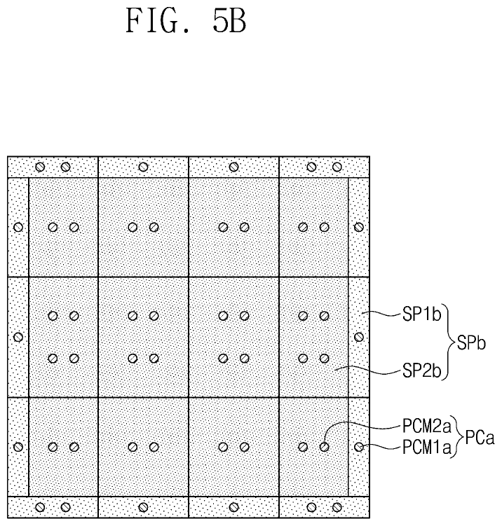

FIGS. 5A and 5B are plan views of support parts according to an embodiment of the invention. As used herein, the “plan view” may be defined as being seen from a third direction DR3. That is, the “plan view” has a same meaning with “on a plane”.

Referring to 5A, a plurality of support parts SP may include a first support part SP1 and a second support part SP2. According to an embodiment of the invention, the first support part SP1 may be disposed on a location corresponding to the frame FR (see FIG. 2). In particular, referring to FIG. 2, since the frame FR is disposed on the rim of the mask MK and supports the mask MK, the first support part SP1 overlapping the frame FR may be a support part, among the plurality of support parts SP, disposed in the outside on a plane. However, an embodiment of the invention is not limited thereto, and the first support part SP1 may be disposed overlapping only a partial region of the frame FR, or disposed overlapping the entire region of the frame FR and a partial region of the mask MK.

The second support part SP2 may be disposed on a location corresponding to the mask MK (see FIG. 2). Referring to FIG. 2, the mask MK may be disposed inside of the frame FR and may thus have an integrated plate shape. Therefore, the second support part SP2 overlapping the mask MK may be a support part, among the plurality of support parts SP, disposed in the inside region on a plane. However, an embodiment of the invention is not limited thereto, and the second support part SP2 may be disposed overlapping only a partial region of the mask MK, or disposed overlapping the entire region of the mask MK and a partial region of the frame FR.

Each of the plurality of support parts SP may have a quadrilateral shape on a plane. However, an embodiment of the invention is not limited thereto, and each of the plurality of support parts SP may have various shapes including polygons such as triangles and pentagons, circles, ovals, and the like. As illustrated in the drawing, the plurality of support parts SP may be different from each other in size and shape. In particular, the first support part SP1 and the second support part SP2 may be different from each other in size and shape. According to an embodiment of the invention, at least one of the first support part SP1 or the second support part SP2 may be provided in plurality. In particular, the first support part SP1 may be provided in plurality, the second support part SP2 may be provided as one, or both of the first support part SP1 and the second support part SP2 may be provided in plurality.

Position control parts PC may be provided in the plurality of support parts SP, respectively. The position control parts PC may each include a first position control module PCM1 provided in the first support part SP1 and a second position control module PCM2 provided in the second support part SP2. FIG. 5A illustrates that one first position control module PCM1 is provided in the first support part SP1, but an embodiment of the invention is not limited thereto. Alternatively, a plurality of first position control modules PCM1 may be provided in the first support part SP1. FIG. 5A illustrates that one second position control module PCM2 is provided in the second support part SP2, but an embodiment of the invention is not limited thereto. Alternatively, a plurality of second position control modules PCM2 may be provided in the second support part SP2.

According to an embodiment of the invention, the second support part SP2 may be movable independently of the first support part SP1. In particular, the second support part SP2 and the first support part SP1 may each include a separate position control part PC, and thus move up and down independently. The first support part SP1 and the second support part SP2 may be each provided in plurality. Each of the plurality of first support parts SP1 may include a separate first position control module PCM1, and thus the plurality of first support parts SP1 may each move up and down independently. Each of the plurality of second support parts SP2 may include a separate second position control module PCM2, and thus the plurality of second support parts SP2 may each move up and down independently.

Referring to FIG. 5B, a plurality of support parts SPb may each include a first support part SP1b and a second support part SP2b. Position control parts PCa may each include a first position control module PCM1a provided in the first support part SP1b and a second position control module PCM2a provided in the second support part SP2b. The first support part SP1b and the second support part SP2b may be each provided in plurality. As the first support part SP1b and the second support part SP2b are each provided in plurality, at least one of the first position control module PCM1a or the second position control module PCM2a may be provided in plurality.

The first support part SP1b and the second support part SP2b may be different from each other in size and shape, and the numbers of the first position control module PCM1a and the second position control module PCM2a may be determined in proportion to the sizes of the first support part SP1b and the second support part SP2b, respectively.

According to an embodiment of the invention, at least one of the first position control module PCM1a included in each of the first support parts SP1b or the second position control module PCM2a included in each of the second support parts SP2b may be provided in plurality. In particular, the first position control module PCM1a included in each of the first support parts SP1b may be all provided in plurality, and the second position control module PCM2a included in each of the second support parts SP2b may be provided as one. Alternatively, the first position control module PCM1a included in each of some first support parts SP1b among the plurality of first support parts SP1b may be provided in plurality, and the second position control module PCM2a included in each of some second support parts SP2b among the plurality of second support parts SP2b may be provided in plurality. However, an embodiment of the invention is not limited thereto, and the number of the first position control module PCM1a included in each of the first support parts SP1b and the number of the second position control module PCM2a included in each of the second support parts SP2b may be variously changed in proportion to the size of the first support part SP1b and the size of the second support part SP2b, respectively. In particular, as the size of each of the plurality of first support parts SP1b on a plane and the size of each of the plurality of second support parts SP2b on a plane are larger, the number of the first position control module PCM1a included in each of the plurality of first support parts SP1b and the number of second position control module PCM2a included in each of the plurality of second support parts SP2b may become greater in proportion to the sizes of the first support part SP1b and the second support part SP2b on a plane, respectively.

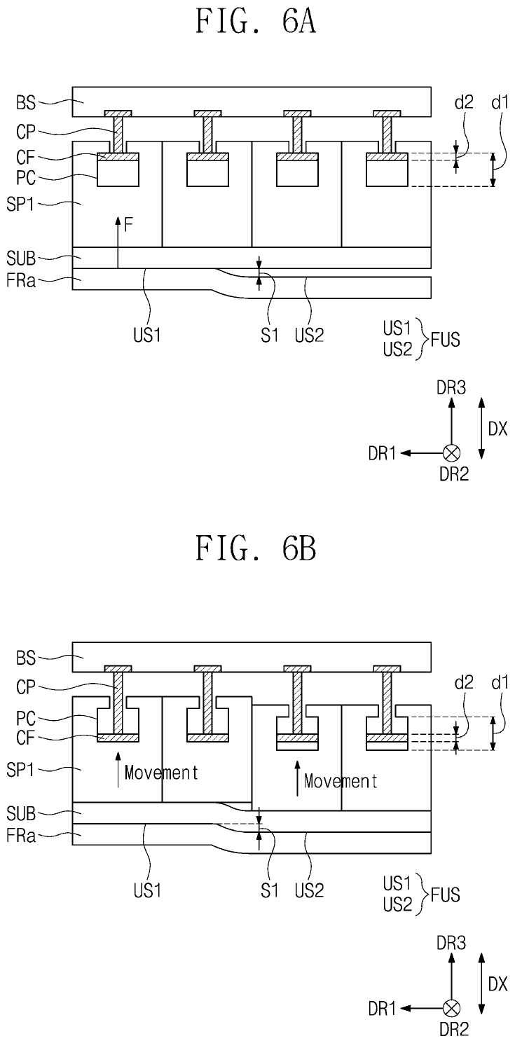

FIGS. 6A and 6B are cross sectional views illustrating a partial configuration of a deposition apparatus according to an embodiment of the invention.

Referring to FIG. 6A, the mask assembly MA (see FIG. 2) may be disposed under a target substrate SUB. The mask assembly MA may include the mask MK (see FIG. 2) and a frame FRa. For the convenience of description, FIG. 6A illustrates only the frame FRa of the mask assembly MA that is disposed under the target substrate SUB.

According to an embodiment of the invention, the frame FRa may have a first step S1 along a third direction DR3 between upper surfaces FUS of the frame FRa. In particular, the upper surface FUS of the frame FRa may include a first upper surface US1 and a second upper surface US2. The first step S1 may be defined as the height difference between the first upper surface US1 and the second upper surface US2 in the third direction DR3.

In the process of the target substrate SUB coming into contact with the frame FRa, the target substrate SUB may first come into contact with the first upper surface US1 of the frame FRa, and the portion in which the target substrate SUB is not in contact with the frame FRa may not come into contact with the second upper surface US2, thereby creating a gap equal to the first step S1. At this time, the portion of the target substrate SUB overlapping the first upper surface US1 where the target substrate SUB is in contact with the frame FRa receives a force F in the third direction DR3. The portion of the target substrate SUB overlapping the second upper surface US2 where the target substrate SUB is not in contact with the frame FRa does not receive the force F in the third direction DR3, but receives only gravity in the opposite direction of the third direction DR3. Meanwhile, the first support parts SP1 and the target substrate SUB which overlap the first upper surface US1 may move by the first step S1 in the third direction DR3, and when this movement ends, the second upper surface US2 and the target substrate SUB the portion of which overlaps the second upper surface US2 comes into contact with each other. Thereafter, as illustrated in FIG. 6B, the first support parts SP1 overlapping the first upper surface US1 and the second upper surface US2 move in the third direction DR3, the first support parts SP1 overlapping the first upper surface US1 move up to the location where it is possible for the position control part PC to control, that is, move in the third direction DR3 by the difference between the height d1 of the position control part PC and the thickness d2 of a connection bottom part CF, and the first support parts SP1 overlapping the second upper surface US2 move in the third direction DR3 by a distance obtained by subtracting the first step S1 from the distance moved by the first support parts SP1 overlapping the first upper surface US1.

As a comparative example although not illustrated, when a support part, which does not have a position control part PC, has a step on a frame, a gap may be created between a target substrate SUB and the frame, and by the gap, the target substrate SUB may have a shadow in the outer region thereof. Referring to FIG. 6B, the first support parts SP1 according to an embodiment of the invention may further include position control parts PC for controlling the plurality of first support parts SP1 to be movable freely along the direction axis DX, respectively, and thus the gap between the target substrate SUB and the frame FRa may be removed, and the shadow may be effectively prevented, thereby providing a deposition apparatus having reliability.

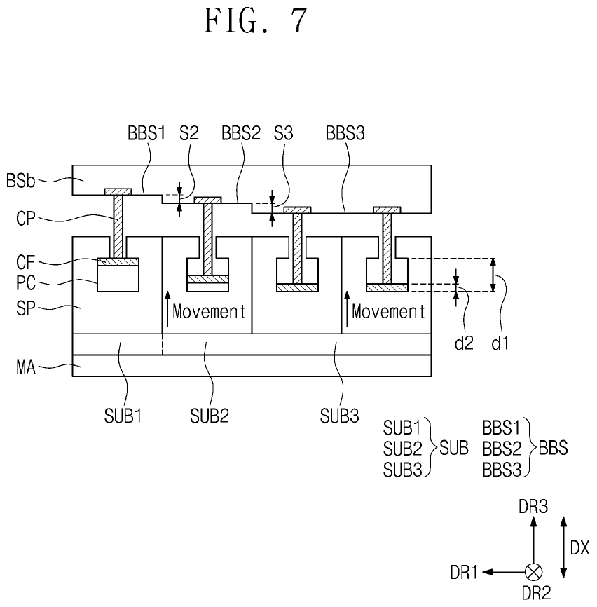

FIG. 7 is a cross-sectional view illustrating a partial configuration of a deposition apparatus according to an embodiment of the invention.

Referring to FIG. 7, a base substrate BSb may include a base lower surface BBS facing a plurality of support parts SP. According to an embodiment of the invention, the base substrate BSb may have a second step S2 and a third step S3 along a third direction DR3 on the base lower surface BBS. In particular, the base lower surface BBS may include a first lower surface BBS1, a second lower surface BBS2, and a third lower surface BBS3. The second step S2 may be defined as the height difference between the first lower surface BBS1 and the second lower surface BBS2 in the third direction DR3, and the third step S3 may be defined as the height difference between the second lower surface BBS2 and the third lower surface BBS3 in the third direction DR3.

Although not illustrated in the drawing, a plurality of support parts SP receive gravity in the opposite direction of the third direction DR3 before a target substrate SUB comes into contact with a mask assembly MA, thereby creating height differences between the plurality of support parts SP corresponding to the steps in the base substrate BSb. That is, there exists a height difference equal to the second step S2 in the third direction DR3 between the support part SP overlapping the first lower surface BBS1 on a plane and the support part SP overlapping the second lower surface BBS2 on a plane, and there exists a height difference equal to the third step S3 in the third direction DR3 between the support part SP overlapping the second lower surface BBS2 on a plane and the support part SP overlapping the third lower surface BBS3 on a plane, before the target substrate SUB comes into contact with the mask assembly MA. In response, the target substrate SUB may also include a first part SUB1 overlapping the first lower surface BBS1 on a plane, a second part SUB2 overlapping the second lower surface BBS2 on a plane, and a third part SUB3 overlapping the third lower surface BBS3 on a plane. The height difference in the third direction DR3 between the first part SUB1 and the second part SUB2 may be equal to the second step S2, and the height difference in the third direction DR3 between the second part SUB2 and the third part SUB3 may be equal to the third step S3, before the target substrate SUB comes into contact with the mask assembly MA.

In the process in which the target substrate SUB having the above-mentioned steps comes into contact with the mask assembly MA, the third part SUB3 may first come into contact with the mask assembly MA, while the first part SUB1 and the second part SUB2 may not be in contact with the mask assembly MA so that a gap may be created between the first part SUB1 and the corresponding part of the mask assembly MA and between the second part SUB2 and the corresponding part of the mask assembly MA. At this time, the third part SUB3 in contact with the mask assembly MA receives normal force (like the force F in FIG. 6A) in the third direction DR3, while the first part SUB1 and the second part SUB2 which are not in contact with the mask assembly MA do not receive normal force in the third direction DR3, but receive only gravity in the opposite direction of the third direction DR3. In this process, the third part SUB3 and the support part SP overlapping the third part SUB3 move by the third step S3 in the third direction DR3. When the movement of the third part SUB3 and the support part SP overlapping the third part SUB3 by the third step S3 in the third direction DR3 is over, the second part SUB2 comes into contact with the mask assembly MA. Through the same process, the plurality of support parts SP overlapping the mask assembly MA move in the third direction DR3. The support parts SP overlapping the third part SUB3 move up to the location where it is possible for the position control part PC to control, that is, move in the third direction DR3 by the difference between a height d1 of the position control part PC and a thickness d2 of a connection bottom part CF, the support part SP overlapping the second part SUB2 moves in the third direction DR3 by a distance obtained by subtracting the third step S3 from the distance moved by the support parts SP overlapping the third part SUB3, and the support part SP overlapping the first part SUB1 moves in the third direction DR3 by a distance obtained by subtracting the second step S2 from the distance moved by the support part SP overlapping the second part SUB2.

The plurality of support parts SP according to an embodiment of the invention may further include position control parts PC for controlling the plurality of support parts SP to be movable freely along the direction axis DX, respectively, and thus, even in case of using the base substrate BSb having a step, a gap between the target substrate SUB and the mask assembly MA may be removed, and a shadow may be effectively prevented, thereby providing a deposition apparatus having reliability.

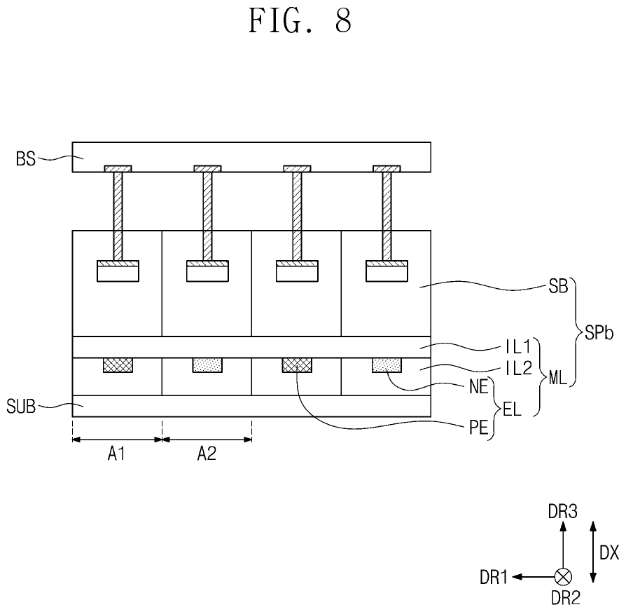

FIG. 8 is a cross-sectional view illustrating a partial configuration of a deposition apparatus according to an embodiment of the invention.

Referring to FIG. 8, support parts SPb may each include a body part SB and a magnetic layer ML. The magnetic layer ML may charge a target substrate SUB to create electrostatic force, and by the electrostatic force, the target substrate SUB may be attached to the support parts SPb. The magnetic layer ML may include a first insulation layer IL1, a second insulation layer IL2, and an electrode EL.

The body part SB may include a material having a predetermined rigidity to provide a base frame for the support parts SPb. The body part SB may include a ceramic material. However, this is an example, and the material of the body part SB according to an embodiment of the invention is not limited thereto. For example, the body part SB according to an embodiment of the invention may include aluminum (Al), titanium (Ti), stainless steel, alumina (Al₂O₃), yttrium oxide (Y₂O₃), or aluminum nitride. Meanwhile, FIG. 8 illustrates that the body part SB is disposed above the first insulation layer IL1, but an embodiment of the invention is not limited thereto, and the body part SB may be disposed under the second insulation layer IL2.

The first insulation layer IL1 may be disposed adjacent to the body part SB. According to an embodiment of the invention, the first insulation layer IL1 may be disposed under the body part SB. The first insulation layer IL1 may include a material having higher thermal resistance and chemical stability than the second insulation layer IL2. For example, the first insulation layer IL1 may include yttrium oxide (Y₂O₃). However, this is an example, and the material of the first insulation layer IL1 according to an embodiment of the invention is not limited thereto, and may include various materials having thermal resistance and chemical stability.

The thickness of the first insulation layer IL1 may be smaller than the thickness of the body part SB. The first insulation layer IL1 may have a thickness of about 80 μm to about 100 μm. The body part SB may have a thickness of about 10 mm to about 20 mm.

The electrode EL may be disposed under the first insulation layer IL1. In particular, at least one electrode EL may be disposed between the first insulation layer IL1 and the second insulation layer IL2. The electrode EL may include a plurality of positive electrodes PE and a plurality of negative electrodes NE. The plurality of positive electrodes PE and the plurality of negative electrodes NE may be disposed between the first insulation layer IL1 and the second insulation layer IL2. The second insulation layer IL2 may cover the plurality of positive electrodes PE and the plurality of negative electrodes NE. The plurality of positive electrodes PE and the plurality of negative electrodes NE may have different polarities. The plurality of positive electrodes PE and the plurality of negative electrodes NE may be alternately disposed.

The plurality of positive electrodes PE and the plurality of negative electrodes NE may each include tungsten (W). However, this is an example, and the materials of the plurality of positive electrodes PE and the plurality of negative electrodes NE according to an embodiment of the invention are not limited thereto. For example, the plurality of positive electrodes PE and the plurality of negative electrodes NE may each include silver (Ag) or copper (Cu).

The plurality of positive electrodes PE and the plurality of negative electrodes NE may have the same thickness. The respective thicknesses of the plurality of positive electrodes PE and the plurality of negative electrodes NE may be smaller than the thicknesses of the first insulation layer IL1 and the second insulation layer IL2. The plurality of positive electrodes PE and the plurality of negative electrodes NE may each have a thickness of about 25 μm to about 35 μm.

Positive DC voltages may be applied to the plurality of positive electrodes PE. Electrostatic force may be generated between the plurality of positive electrodes PE and the target substrate SUB. Negative DC voltages may be applied to the plurality of negative electrodes NE. Electrostatic force may be generated between the plurality of negative electrodes NE and the target substrate SUB. The target substrate SUB may be attached to the support parts SPb by the electrostatic force generated between the plurality of positive electrodes PE and the target substrate SUB, and between the plurality of negative electrodes NE and the target substrate SUB. The support parts SPb according to an embodiment of the invention may be bipolar electrostatic chucks. However, this is an example, and the type of the support parts SPb according to an embodiment of the invention is not limited thereto. For example, the support parts SPb may be monopolar electrostatic chucks. In this case, DC voltages having the same polarity may be applied to the plurality of positive electrodes PE and the plurality of negative electrodes NE of the support parts SPb.

When the positive DC voltage is applied to each of the plurality of positive electrodes PE, the upper portion of a first region A1 of the target substrate SUB overlapping each of the plurality of positive electrodes PE on a plane may be charged with a negative potential. Electrostatic force may be generated by the charge between the plurality of positive electrodes PE and the first region A1.

When the negative DC voltage is applied to each of the plurality of negative electrodes NE, the upper portion of a second region A2 of the target substrate SUB overlapping each of the plurality of negative electrodes NE on a plane may be charged with a positive potential. Electrostatic force may be generated by the charge between the plurality of negative electrodes NE and the second region A2.

The second insulation layer IL2 may be disposed under the plurality of electrodes PE and NE. The second insulation layer IL2 may include a material having higher heat conductivity and dielectric characteristics than the first insulation layer IL1. For example, the second insulation layer IL2 may include alumina (Al₂O₂). However, this is an example, and the material of the second insulation layer IL2 according to an embodiment of the invention is not limited thereto, and may include various materials having heat conductivity.

The thickness of the second insulation layer IL2 may be larger than the thickness of the first insulation layer IL′. The thickness of the second insulation layer IL2 may be smaller than the thickness of the body part SB. The thickness of the second insulation layer IL2 may be about 110 μm to about 150 μm.

According to an embodiment of the invention, the plurality of support parts SPb may each include at least one electrode EL. In particular, each of the plurality of support parts SPb may include at least one of the positive electrode PE or the negative electrode NE. However, an embodiment of the invention is not limited thereto, and each of the plurality of support parts SPb may include both of the positive electrode PE and the negative electrode NE, or may include a plurality of positive electrodes PE and a plurality of negative electrodes NE. Since each of the plurality of support parts SPb includes at least one of the positive electrode PE or the negative electrode NE, electrostatic force may be generated by electrostatic induction between each of the plurality of support parts SPb and the target substrate SUB. Each of the plurality of support parts SPb may chuck or de-chuck the target substrate SUB by using the electrostatic force.

According to an embodiment of the invention, the plurality of electrodes PE and NE may be driven for each of the plurality of support parts SPb. In particular, a positive or negative DC voltage may be applied to the positive electrode PE or the negative electrode NE included in each of the plurality of support parts SPb. The plurality of support parts SPb may be separated from each other, and may each be movable independently. The positive electrode PE or the negative electrode NE included in each of the plurality of support parts SPb may have electrostatic force, which is generated by charges, independently of each other. Accordingly, each of the plurality of support parts SPb may independently use electrostatic force to chuck or de-chuck the target substrate SUB.

Position control parts PC may be provided in the support parts SPb. According to an embodiment of the invention, the position control parts PC may be provided in the body part SB of the support parts SPb. The body part SB may include a material having rigidity, and may serve to protect the electrode EL, etc. Disposing the position control parts PC on the magnetic layer ML may affect the electrode EL, etc., and disposing the position control parts PC in the body part SB makes it possible to control the movement of the support parts SPb and thus, the position control parts PC may not affect the electrode EL.

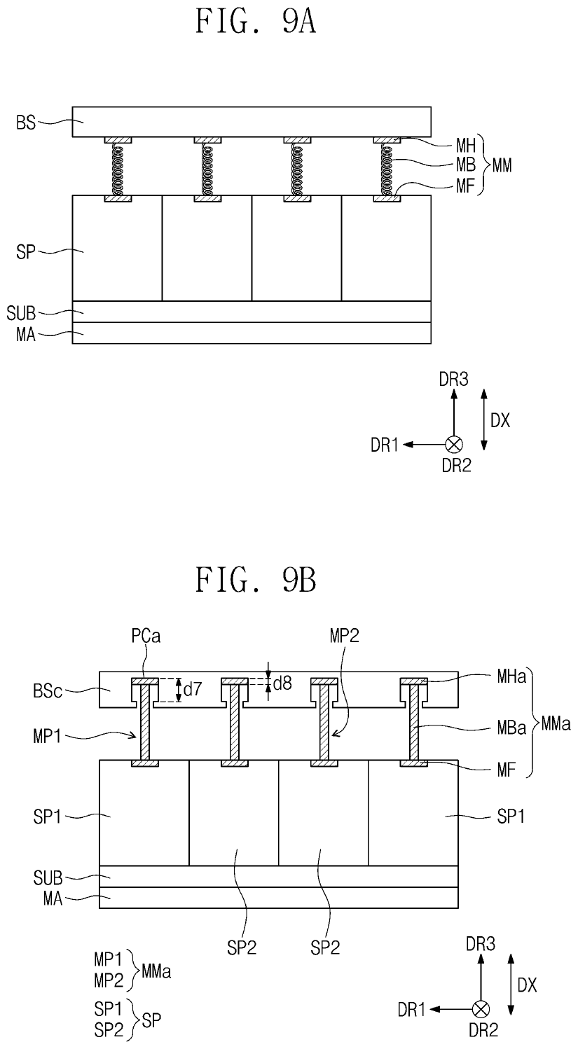

FIGS. 9A and 9B are cross-sectional views each illustrating a partial configuration of a deposition apparatus according to an embodiment of the invention.

Referring to FIG. 9A, movement modules MM may be disposed on a plurality of support parts SP. The movement modules MM may connect a base substrate BS to the plurality of support parts SP, and may be fixed to the base substrate BS. The movement modules MM may be coupled to the plurality of support parts SP such that the plurality of support parts SP are movable along a direction axis DX perpendicular to a major surface of each of the plurality of support parts SP defined by the first and second directions DR1 and DR2.

According to an embodiment of the invention, at least one movement module MM may be correspondingly coupled to each of the plurality of support parts SP. That is, one movement module MM may be disposed to correspond to each of the plurality of support parts SP. However, an embodiment of the invention is not limited thereto, and a plurality of movement modules MM may be disposed on each of the plurality of support parts SP. According to an embodiment of the invention, the plurality of movement modules MM may each have a circular shape on a plane, but the shape thereof is not limited thereto, and the plurality of movement modules MM may each have various shapes including polygons such as triangles and quadrangles, ovals, and the like. The material of the plurality of movement modules MM may not be limited, but may include, for example, a metal material, an elastic material, or the like.

The movement modules MM may each include a movement head part MH fixed to the base substrate BS, a movement body part MB, and a movement bottom part MF fixed to each of the plurality of support parts SP.

The movement bottom part MF may be fixed to the upper surfaces of the plurality of support parts SP while contacting the upper surfaces of the plurality of support parts SP. According to what is illustrated in the drawing, the shape of the movement bottom part MF is fixed as a rectangle in cross section, but the shape thereof is not limited thereto, and may include a trapezoid, a semi-sphere, or the like.

The movement body part MB, which is a part for connecting the movement head part MH to the movement bottom part MF, may be an elastic member. In particular, when the movement body part MB is an elastic member, due to the gravity applied to the plurality of support parts SP, the movement body part MB may extend from the lower surface of the base substrate BS in the opposite direction of a third direction DR3. When the movement modules MM are disposed under the plurality of support parts SP, the movement body part MB may be contracted, due to the gravity applied to the plurality of support parts SP, in the direction toward the lower surface of the base substrate BS, that is, in the opposite direction of the third direction DR3. That is, each of the plurality of support parts SP may be movable freely along the direction axis DX by the movement body part MB.

The movement head part MH may be fixed to a base substrate BS. In particular, it is illustrated that the movement head part MH is fixed to the base substrate BS, but an embodiment of the invention is not limited thereto. It is illustrated that the movement head part MEI has a rectangular shape in cross section, but the shape is not limited thereto.

Referring to FIG. 9A, a target substrate SUB may be attached under the plurality of support parts SP, and the target substrate SUB may come into contact with a mask assembly MA so that each of the plurality of support parts SP receives force in the third direction DR3 and moves in the third direction DR3. Although not illustrated in the drawing, even when a step is present in the mask assembly MA, a deposition apparatus according to an embodiment of the invention includes the movement modules MM which make it possible for each of the plurality of support parts SP to be movable freely up and down along the direction axis DX, and may thus remove a gap between the target substrate SUB and the mask assembly MA and effectively prevent a shadow, thereby achieving reliability.

Referring to FIG. 9B, a base substrate BSc may include position control parts PCa for controlling a plurality of support parts SP to be movable along a direction axis DX perpendicular to a major surface of each of the support parts SP, respectively.

Movement modules MMa may each include a movement head part MHa connected to the base substrate BSc, a movement body part MBa, and a movement bottom part MF fixed to each of the plurality of support parts SP.

The plurality of support parts SP may each include a first support part SP1 and a second support part SP2. The first support part SP1 may be disposed on a location corresponding to the frame FR (see FIG. 2). The second support part SP2 may be disposed on a location corresponding to the mask MK (see FIG. 2). For the convenience of description, FIG. 9B illustrates that a mask assembly MA is disposed under a target substrate SUB.

The movement bottom part MF may be fixed to the upper surfaces of the plurality of support parts SP while contacting the upper surfaces of the plurality of support parts SP. In particular, the movement bottom part MF may be fixed to the upper surface of each of the first support part SP1 and the second support part SP2.

The movement head part MHa may be fixed in the position control part PCa included in the base substrate BSc. According to what is illustrated in the drawing, the shape of the movement head part MHa is fixed as a rectangle in cross section, but the shape is not limited thereto. The movement head parts MHa may serve to limit the respective ranges in which the plurality of support parts SP are movable in the position control parts PCa.

The movement body part MBa may be a part for connecting the movement head part MHa to the movement bottom part MF, and may have a stick shape in cross section. The movement body part MBa may have a material same as the materials of the movement head part MHa and the movement bottom part MF. However, an embodiment of the invention is not limited thereto, and the movement body part MB may be an elastic member.

According to an embodiment of the invention, the base substrate BSc may include a plurality of position control parts PCa which correspond to the plurality of movement modules MMa. In particular, the position control parts PCa may be spaces in which the movement head parts MHa connected to the base substrate BSc are provided. The position control parts PCa may control the plurality of support parts SP to be movable along a direction axis DX, respectively. In particular, when a height d7 of the position control part PCa along the third direction DR3 and a thickness d8 of the movement head part MHa along the third direction DR3 are defined, the movable range of each of the plurality of support parts SP may be set by the difference between the height d7 of the position control part PCa and the thickness d8 of the movement head part MHa.

FIG. 9B illustrates that the target substrate SUB is attached under the plurality of support parts SP, and the target substrate SUB comes into contact with the mask assembly MA so that each of the plurality of support parts SP receives force in the third direction DR3 and moves maximally in the third direction DR3. Although not illustrated in the drawing, according to a comparative example in which the mask assembly MA is omitted, each of the plurality of support parts SP receives gravity in the opposite direction of the third direction DR3, and moves maximally in the opposite direction of the third direction DR3 due to the gravity. Accordingly, in the position control part PCa, the movement head part MHa reflectively moves in the opposite direction of the third direction DR3 until the movement head part MHa reaches the lower surface of the position control part PCa. That is, each of the plurality of support parts SP according to an embodiment of the invention is movable freely up and down along the direction axis DX by the difference between the height d7 of the position control part PCa along the third direction DR3 and the thickness d8 of the movement head part MHa along the third direction DR3 in the process of the target substrate SUB coming into contact with the mask assembly MA.

The movement module MMa may include a first movement member MP1 coupled to the first support part SP1 and a second movement member MP2 coupled to the second support part SP2. According to an embodiment of the invention, since the first support part SP1 and the second support part SP2 are each provided in plurality, at least one of the first movement member MP1 or the second movement member MP2 may be provided in plurality. For example, the first movement member MP1 coupled to the first support part SP1 may be all provided in plurality, and the second movement member MP2 coupled to the second support part SP2 may be provided as one.

When a mask frame has a step, a gap is created between a substrate and the mask frame, and by the gap, a shadow is created in the outer region of the substrate. According to an embodiment of the invention, a support module that fixes a mask includes a plurality of support parts, and further includes position control parts for controlling the plurality of support parts to be movable freely up and down, respectively, thereby removing the gap between the substrate and the mask frame, and effectively preventing the shadow.

Although the embodiments of the invention have been described, it is understood that the invention should not be limited to these embodiments but various changes and modifications can be made by one ordinary skilled in the art within the spirit and scope of the invention as hereinafter claimed.

Therefore, the technical scope of the invention should not be limited to the contents described in the detailed description of the specification, but should be defined by the claims.

What is claimed is:

1. A deposition apparatus comprising:
a support module including a plurality of support parts coupled to a target substrate;
a base substrate coupled to the support module;
a connection member for connecting the plurality of support parts to the base substrate; and
a mask assembly adjacent to the target substrate, and configured to mask a deposition material provided to the target substrate,
wherein the support module further includes position control parts configured to control the plurality of support parts, respectively, to be movable along a direction axis perpendicular to a major surface of each of the support parts.

2. The deposition apparatus of claim 1, wherein each of the plurality of support parts comprises at least one of the position control parts.

3. The deposition apparatus of claim 1, wherein the mask assembly comprises:
a mask including a plurality of cells; and
a frame configured to support the mask.

4. The deposition apparatus of claim 3, wherein the plurality of support parts comprise:
a first support part disposed on a location corresponding to the frame; and
a second support part which is movable independently of the first support part.

5. The deposition apparatus of claim 4, wherein at least one of the first support part or the second support part is provided in plurality.

6. The deposition apparatus of claim 4, wherein the frame has a step on a surface thereof in contact with the target substrate, and
the position control part comprises a first position control module provided in the first support part and a second position control module provided in the second support part.

7. The deposition apparatus of claim 6, wherein at least one of the first position control module or the second position control module is provided in plurality.

8. The deposition apparatus of claim 1, wherein the base substrate comprises a separation film for separating the plurality of support parts from each other.

9. The deposition apparatus of claim 1, wherein each of the plurality of support parts comprises a body part and a magnetic layer fixed to the body part, and
the magnetic layer includes:
a first insulation layer disposed adjacent to the body part;
an electrode disposed under the first insulation layer; and
a second insulation layer disposed under the at least one electrode.

10. The deposition apparatus of claim 9, wherein the electrode is provided in plurality, and
each of the plurality of support parts comprises at least one of the electrodes.

11. The deposition apparatus of claim 10, wherein the plurality of electrodes are driven for the plurality of support parts, respectively.

12. The deposition apparatus of claim 9, wherein the position control part is provided in the body part.

13. A deposition apparatus comprising:
a support module including a plurality of support parts coupled to a target substrate;
a movement module coupled to the plurality of support parts such that the plurality of support parts each are movable along a direction axis perpendicular to a major surface of each of the support parts; and
a mask assembly adjacent to the target substrate, and configured to mask a deposition material provided to the target substrate.

14. The deposition apparatus of claim 13, wherein the movement module is provided in plurality, and the plurality of movement modules are coupled to the plurality of support parts, respectively.

15. The deposition apparatus of claim 13, wherein the mask assembly comprises:
a mask including a plurality of cells; and
a frame configured to support the mask.

16. The deposition apparatus of claim 15, wherein the plurality of support parts comprise:
a first support part disposed on a location corresponding to the frame; and
a second support part which is movable independently of the first support part,
wherein at least one of the first support part or the second support part is provided in plurality.

17. The deposition apparatus of claim 16, wherein the frame has a step on a surface thereof in contact with the target substrate,
the movement module comprises a first movement member coupled to the first support part, and a second movement member coupled to the second support part, and
at least one of the first movement member or the second movement member is provided in plurality.

18. The deposition apparatus of claim 13, further comprising a base substrate coupled to the support module.

19. The deposition apparatus of claim 18, wherein the base substrate comprises position control parts configured to control the plurality of support parts to be movable along the direction axis perpendicular to the major surface of each of the support parts, respectively.

20. The deposition apparatus of claim 13, wherein the plurality of support parts comprise:
a first insulation layer;
a plurality of electrodes disposed on the first insulation layer; and
a second insulation layer disposed on the plurality of electrodes.
